(19) United States
(12) Patent Application Publication
(10) Pub. No.: US 2026/0348001 A1
(43) Pub. Date: Nov. 5, 2026

(54) INHIBITED ATOMIC LAYER DEPOSITION IN TRENCH FEATURES

(71) Applicant: Lam Research Corporation, Fremont, CA (US)

(72) Inventors: Shiva Sharan BHANDARI, Beaverton, OR (US); Pulkit AGARWAL, Beaverton, OR (US); Jennifer Leigh PETRAGLIA, Lake Oswego, OR (US); Aaron FELLIS, Lake Oswego, OR (US)

(21) Appl. No.: 19/482,727

(22) PCT Filed: May 20, 2024
(86) PCT No.: PCT/US2024/030235

§ 371 Date: Nov. 7, 2025

Related U.S. Application Data
(60) Provisional application No. 63/503,919, filed on May 23, 2023.

(51) Int. Cl. C23C 16/04; C23C 16/02; C23C 16/30; C23C 16/34; C23C 16/40; C23C 16/455; H10P 14/60; H10P 14/692; H10P 14/694; H10W 10/17

(52) U.S. Cl. CPC C23C 16/045; C23C 16/02; C23C 16/45527; H10P 14/6339; H10W 10/17; C23C 16/308; C23C 16/345; C23C 16/402; H10P 14/69215; H10P 14/6927; H10P 14/69433

(57) ABSTRACT

Examples are disclosed that relate to using an inhibitor with an ALD deposition process to fill trench features with a dielectric gapfill material. One example provides a method of processing a substrate comprising a deep trench feature comprising a polysilicon surface with reentrant features. The method comprises performing an inhibition cycle comprising depositing an inhibitor on the substrate under conditions that deposit a greater concentration of the inhibitor at a first depth within the trench feature than at a second depth within the trench feature. The second depth is deeper within the trench feature than the first depth. The method further comprises performing a plurality of ALD cycles, the inhibitor inhibiting growth of the dielectric gapfill material such that a layer of the dielectric gapfill material grows at a higher rate at the second depth relative to the first depth.

### BACKGROUND

Semiconductor device fabrication processes involves many steps of material deposition, patterning and removal to form integrated circuits on substrates. Various methods can be used to deposit films of materials onto a substrate. As an example, atomic layer deposition (ALD) forms a film using one or more deposition cycles. In an ALD deposition cycle, a film precursor is adsorbed onto a surface of a substrate disposed in a process chamber. Excess film precursor is purged from the chamber, and the adsorbed film precursor is chemically converted into a film on the substrate, for example, by oxidation. A highly conformal film of a target thickness can be grown using one or more deposition cycles.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to performing inhibited deposition of dielectric gapfill materials in trench features. One example provides a method of processing a substrate. The substrate comprises a trench feature comprising a polysilicon surface. The polysilicon surface comprises reentrant features. The method comprises performing an inhibition cycle. The inhibition cycle comprises depositing an inhibitor on the substrate under conditions that deposit a greater concentration of the inhibitor at a first depth within the trench feature than at a second depth within the trench feature. The second depth is deeper within the trench feature than the first depth. The method further comprises performing a plurality of atomic layer deposition (ALD) cycles to fill the trench feature with a dielectric gapfill material. The deposited inhibitor inhibits growth of the dielectric gapfill material such that the layer of the dielectric gapfill material grows at a higher rate at the second depth relative to the first depth to fill the trench feature.

In some such examples, the trench is filled without a void.

In some such examples, the inhibitor alternatively or additionally comprises a halogen-containing inhibitor.

In some such examples, the halogen-containing inhibitor alternatively or additionally comprises a fluorine-containing inhibitor.

In some such examples, the inhibitor alternatively or additionally comprises a nitrogen-containing inhibitor.

In some such examples, the inhibitor alternatively or additionally comprises a carbon-containing inhibitor.

In some such examples, the dielectric gapfill material alternatively or additionally comprises silicon dioxide.

In some such examples, the dielectric gapfill material alternatively or additionally comprises silicon nitride, silicon oxynitride, or silicon oxycarbide.

In some such examples, the method alternatively or additionally comprises performing an additional inhibition cycle between ALD cycles of the plurality of ALD cycles.

In some such examples, the method alternatively or additionally comprises depositing a silicon oxide liner by thermal atomic layer deposition prior to performing the inhibition cycle.

In some such examples, the method alternatively or additionally comprises a passivation step to remove at least some of the inhibitor from the substrate.

In some such examples, the trench feature alternatively or additionally comprises one or more of a slit, a hole, a ring, a 3-way street structure or a 4-way street structure.

Another example provides an atomic layer deposition (ALD) tool. The tool comprises a processing chamber, a dielectric gapfill precursor source comprising a dielectric gapfill precursor and a reactant source comprising a reactant. The ALD tool further comprises an inhibitor source comprising an inhibitor and flow control hardware fluidly connecting the dielectric gapfill precursor source, the reactant source, and the inhibitor source to the processing chamber. The ALD tool further comprises a controller configured to control the ALD tool. The controller is configured to operate the flow control hardware to perform an inhibition cycle in which the inhibitor is introduced into the processing chamber. The inhibitor is introduced into the processing chamber under conditions selected to deposit a greater concentration of the inhibitor at a first depth within a trench feature on a substrate and a lesser concentration of inhibitor at a second depth within the trench feature. The second depth is deeper within the trench feature than the first depth. The controller is further configured to operate the flow control hardware to perform a plurality of ALD cycles. Each ALD cycle comprises controlling the flow control hardware to introduce the dielectric gapfill precursor into the processing chamber and then introduce the reactant into the processing chamber. Each ALD cycle further comprises controlling the flow control hardware to operate the radiofrequency power source to form a plasma in the processing chamber, during the introduction of the silicon oxide precursor and reactant into the chamber, to fill the trench feature with the dielectric gapfill material.

In some such examples, the inhibitor alternatively or additionally comprises a halogen-containing inhibitor.

In some such examples, the inhibitor alternatively or additionally comprises a nitrogen-containing inhibitor.

In some such examples, the inhibitor alternatively or additionally comprises a carbon-containing inhibitor

In some such examples, the controller alternatively or additionally is further configured to control the ALD tool to perform a passivation step to remove at least some of the inhibitor from the substrate.

Another example provides a method of processing a substrate. The substrate comprises a trench feature, the trench feature comprising a polysilicon surface. The polysilicon surface comprises reentrant features. The method comprises performing an inhibition cycle. The inhibition cycle comprises depositing an inhibitor on the substrate under conditions that deposit a greater concentration of the inhibitor at a first depth within the trench feature than at a second depth within the trench feature. The second depth is deeper within the trench feature than the first depth. The method further comprises performing a plurality of ALD cycles to fill the trench feature with a dielectric gapfill material. The deposited inhibitor inhibits growth of the dielectric gapfill material such that the layer of dielectric gapfill material grows at a higher rate at the second depth relative to the first depth. The method further comprises processing a backside of the substrate to expose at least part of the trench feature.

In some such examples, the inhibitor alternatively or additionally comprises a halogen-containing inhibitor.

In some such examples, the inhibitor alternatively or additionally comprises a nitrogen-containing inhibitor or a carbon-containing inhibitor.

In some such examples, the method alternatively or additionally comprises depositing a silicon oxide liner by thermal atomic layer deposition prior to performing the inhibition cycle.

In some such examples, the method alternatively or additionally comprises a passivation step to remove at least some of the inhibitor from the substrate.

In some such examples, alternatively or additionally the trench is filled without a void.

### BRIEF DESCRIPTION OF THE DRAWINGS

FIGS. 1A-1C schematically show the formation of voids in trench features during an example atomic layer deposition (ALD) process without an inhibitor.

FIG. 2 shows a block diagram of an example processing tool.

FIGS. 3A-3B show a flow diagram illustrating an example process for filling deep trench isolation (DTI) features by an inhibited ALD process.

FIGS. 4A-4D schematically show formation of a voidless gapfill of deep trench isolation features using an example inhibited ALD process.

FIG. 5 shows a flow diagram illustrating an example method for performing ALD processing using a plurality of ALD cycles and an equal number of inhibition and passivation cycles.

FIG. 6 shows a flow diagram illustrating an example method for performing ALD processing using a plurality of ALD cycles and unequal number of inhibition and passivation cycles.

FIG. 7 shows a flow diagram illustrating an example method for performing ALD processing using a plurality of ALD cycles and inhibition cycles with no passivation.

FIG. 8 shows a flow diagram illustrating an example method for performing ALD processing using a plurality of ALD cycles and inhibition cycles and a final passivation cycle.

FIG. 9 shows a flow diagram illustrating an example sequence for performing ALD processing using a plurality of ALD cycles, inhibition cycles and passivation cycles performed at one or more of a same pressure or a same gas flow rate.

FIG. 10 shows a flow diagram illustrating an example sequence for performing ALD processing using a plurality of ALD cycles and inhibition cycles performed at one or more of a same pressure or a same gas flow rate, and with no passivation.

FIG. 11 shows a flow diagram illustrating an example sequence for performing ALD processing using a plurality of ALD cycles with no passivation and using a combined oxidation and inhibition cycle.

FIG. 12 shows a block diagram of an example computing device.

### DETAILED DESCRIPTION

The term “alcohol” generally represents hydrocarbon compounds comprising a general formula of R—OH, where R is an unsubstituted, partially substituted, or fully substituted aromatic or aliphatic group. Alcohols can have more than one OH group (polyols). For example, diols have two OH functional groups. Example alcohols comprise methanol, ethanol, and propanol.

The term “aldehyde” generally represents hydrocarbon compounds comprising a terminal carbonyl group. Aldehydes comprise a general formula of R—CHO, where R is an unsubstituted, partially substituted, or fully substituted aromatic or aliphatic group. Example aldehydes comprise formaldehyde and acetaldehyde.

The term “alkane” generally represents compounds comprising a general formula CₙH₂ₙ₊₂ and partially or fully substituted variants thereof. Example alkanes include methane, ethane, propane, and butane.

The term “alkene” generally represents hydrocarbon compounds comprising at least one carbon-carbon double bond, and partially and fully substituted variants thereof. Alkanes comprising one carbon-carbon double bond can be represented by a general formula of CₙH₂ₙ and partially or fully substituted variants thereof. Example alkenes include ethylene, propylene, and butylenes. Alkenes can have more than one carbon-carbon double bond, such as dienes, allenes, and cumulenes.

The term “alkyl amine” generally represents hydrocarbon compounds comprising a nitrogen with 1 to 3 alkyl substituents (including partially or fully substituted variants thereof) and 0 to 2 H substituents. Alkyl amines can comprise primary, secondary, tertiary, and cyclic amines. Examples of alkyl amines include methylamine, dimethylamine, trimethylamine, and piperidine.

The term “alkyl halide” generally represents hydrocarbon compounds comprising a halogen. Examples of alkyl halides comprise ethyl fluoride (fluoroethane), isopropyl bromide (2-bromopropane), and t-butyl chloride (2-chloro-2-methylpropane). Alkyl halides can comprise two or more halogen groups, such as 1,2-dichlorobutane.

The term “alkyne” generally represents hydrocarbon compounds comprising at least one carbon-carbon triple bond, including partially and fully substituted variants thereof. Alkynes comprising one carbon-carbon triple can be represented by a general formula of CₙH₂ₙ₋₂. Alkynes can have more than one carbon-carbon triple bond, such as diynes, which have two carbon-carbon triple bonds.

The term “aspect ratio” generally represents a ratio of a depth or height of a feature to an average width of the feature. The term “high aspect ratio” represents an aspect ratio greater than or equal to 2.

The term “atomic layer deposition” (ALD) generally represents a process in which a film is formed on a substrate in one or more individual layers by sequentially adsorbing a precursor to a substrate and then chemically transforming the adsorbed precursor to form a film layer. Examples of ALD processes comprise plasma-enhanced ALD (PEALD) and thermal ALD (TALD). PEALD and TALD respectively utilize a plasma of a reactive gas and heat to facilitate a chemical conversion of a precursor adsorbed to a substrate to a film on the substrate. The term “remote plasma enhanced atomic layer deposition” (RPEALD) generally represents an ALD process that utilizes a remote plasma to generate reactive gas species. The terms “growth”, “deposition”, and variants thereof, also can be used to refer to film formation. A silicon oxide film is an example of a film that can be deposited by ALD.

The term “ALD cycle” generally represents a single cycle of adsorbing a chemical precursor on a substrate surface and then chemically transforming the adsorbed chemical precursor to form a film layer on the substrate. The term “dielectric gapfill material ALD cycle” generally represents an ALD cycle that deposits a layer of a dielectric gapfill material.

The term “controller” generally represents a computing system that is configured to control the hardware components of a processing tool.

The term “cyclic hydrocarbon” generally represents saturated and unsaturated hydrocarbon molecules comprising a closed ring structure, and partially or fully substituted variants thereof. Example cyclic hydrocarbons include cyclopropane and cyclobutane. Example cyclic hydrocarbons also include aromatics such as benzene, toluene, and xylene.

The term “trench feature” generally represents a recessed substrate structure that can be filled with a dielectric gap material. The term “deep trench isolation feature” generally represents an electrically insulating trench feature in an integrated circuit that electrically isolates transistors, memory cells or other electrical components. Deep trench isolation features can be microns deep in some examples. Deep trench isolation features can be filled with a dielectric gapfill material to form a deep trench isolation structure. Example deep trench isolation features can include slits, holes, rings, 3-way street structures, and 4-way street structures. In some examples, such structures can have critical dimensions within a range of 0.01-0.25 μm. The term “slit” generally represents a gap extending linearly in one direction. The term “hole” generally represents a generally elliptically-shaped gap (e.g. a round gap)._. The term “ring” generally represents a generally elliptically-shaped gap that surrounds an unrecessed center. The term “3-way street” generally represents a slit that terminates at an intersection with another slit. The term “four-way street” generally represents slits that intersect and extend in four directions away from the intersection.

The term “dielectric gapfill material” generally refers to an electrically insulating material that can be used to fill a deep trench isolation feature. Examples of dielectric gapfill materials include silicon-containing dielectric materials. Example silicon-containing dielectric materials include silicon dioxide, silicon oxynitride, silicon oxycarbide and silicon nitride.

The term “ether” generally represents hydrocarbon compounds comprising the general formula R—O—R′ where R and R′ are independently an unsubstituted, partially substituted, or fully substituted aromatic or aliphatic group. Example ethers comprise diethyl ether, methyl phenyl ether, and cyclic ethers such as furan.

The term “ester” generally represents hydrocarbon compounds comprising the general formula R—C(O)OR′ where R and R′ are independently unsubstituted, partially substituted, or fully substituted aromatic or aliphatic group and wherein R can alternatively comprise H. Examples esters comprise ethyl formate, methyl acetate, and ethyl acetate.

The term “gap” generally represents a recessed feature in a substrate.

The term “inhibition cycle” generally represents a process comprising introducing an inhibitor onto a substrate.

The term “inhibitor” generally represents a compound that can be deposited nonconformally on a substrate surface to inhibit ALD growth of a film. Example inhibitors can include nitrogen-containing inhibitors, halogen-containing inhibitors, and carbon-containing inhibitors.

Examples of nitrogen-containing inhibitors can include nitrogen (N₂), ammonia (NH₃), nitrogen and hydrogen mixtures, amines, diamines, and aminoalcohols.

Examples of halogen-containing inhibitors can include fluorine-containing inhibitors, chlorine-containing inhibitors, bromine-containing inhibitors, and iodine-containing inhibitors. Examples of fluorine-containing inhibitors can include molecular fluorine (F₂), hydrogen fluoride (HF), boron trifluoride (BF₃), phosphorus trifluoride (PF₃), nitrogen trifluoride (NF₃), chlorine trifluoride (ClF₃), chlorine pentafluoride (ClF₅), sulfur tetrafluoride (SF₄), and sulfur hexafluoride (SF₆). Further examples of fluorine-containing inhibitors can include chalcogen fluorides such as selenium tetrafluoride (SeF₄), selenium hexafluoride (SeF₆), and tellurium hexafluoride (TeF₆). Further examples of fluorine-containing inhibitors can include chlorofluorocarbons such as trichlorofluoromethane (CCl₃F), fluorocarbons such as carbon tetrafluoride (CF₄) or hexafluoroethane (C₂F₆), and hydrofluorocarbons such as difluoromethane (CH₂F₂). Further examples of halogen-containing inhibitors can include chlorine (Cl₂), hydrogen chloride (HCl), carbon tetrachloride (CCl₄), bromine (Br₂), hydrogen bromide (HBr), iodine (I₂), hydrogen iodide (HI), and 1,2-diiodoethane (C₂H₄I₂).

Examples of suitable carbon-containing inhibitors can include alkanes, alkenes, alkynes, cyclic hydrocarbons, aromatics, alcohols, aldehydes, esters, ethers, ketones, aldehydes, alkyl halides, alkyl amines, and alkyl diamines. In some examples, the carbon-containing inhibitor can comprise an alkane comprising a general formula CₙH₂ₙ₊₂ in which n=1 to 10. Examples of suitable alkanes can include methane, ethane, propane, butane, pentane, hexane, and substituted alkanes. Other examples of carbon-containing inhibitors can include alkenes, alkynes, cyclic hydrocarbons including aromatics, alcohols, aldehydes, esters, ethers, ketones, alkyl halides, and alkyl amines. In still other examples, the carbon-containing inhibitor can include a mixture of carbon-containing inhibitors. Examples of suitable alkenes (CₙH₂ₙ in which n=2 to 10, for an alkene with a single carbon-carbon double bond) can include ethene, propene, and butene. Examples of suitable alkynes (CₙH₂ₙ₋₂ in which n=2 to 10, for an alkyne with a single carbon-carbon triple bond) can include acetylene, propyne, and butyne. Examples of suitable cyclic hydrocarbons can include cyclobutene, cyclopentane cyclohexane, benzene, toluene, pyridine, and pyrimidine. Examples of suitable alcohols can include methanol, ethanol, and propanol. Examples of suitable diols can include ethylene glycol, propylene glycol, and hydroquinone. Examples of suitable aldehydes can include formaldehyde and acetaldehyde. Examples of suitable esters can include ethyl formate, methyl acetate, and ethyl acetate. Examples of suitable ethers can include diethyl ether, methyl phenyl ether, and aromatic ethers such as furan. Examples of suitable ketones can include acetone and methyl ethyl ketone. Examples of suitable alkyl halides can include ethyl fluoride, isopropyl bromide, and t-butyl chloride. Examples of suitable alkyl amines can include methylamine, dimethylamine, trimethylamine, piperidine, ethylenediamine and 1,3-diaminopropane. The term “ketone” generally represents hydrocarbon compounds comprising a non-terminal carbonyl. Ketones have the general formula R—C(O)—R′ where R and R′ are independently an aromatic or aliphatic group, including unsubstituted, partially substituted, and fully substituted variants thereof. Example ketones comprise acetone and methyl ethyl ketone.

The term “oxidant” generally represents a gas species containing oxygen available for reacting with a film precursor to form a silicon-containing material film. Examples of oxidants comprise molecular oxygen (O₂), water vapor (H₂O), hydrogen peroxide (H₂O₂), ozone (O₃) and ammonia (NH₃).

The term “passivation” generally represents removal of residual inhibitor from a substrate surface.

The term “passivation cycle” generally represents a sequence of steps to perform passivation.

The term “plasma” generally represents a gas phase material comprising ions and free electrons.

The term “processing chamber” generally represents an enclosure in which chemical and/or physical processes are performed on substrates. The pressure, temperature and atmospheric composition within a processing chamber is controllable to perform the chemical and/or physical processes.

The term “reentrant feature” generally represents a location in a recessed feature of a substrate that is that is narrower at a first depth within the recessed feature than at a second depth within the recessed feature, wherein the second depth is deeper within the recessed feature than the first depth.

The term “remote plasma” generally represents a plasma used to produce reactive chemical species at a location remote from a surface being processed with the reactive chemical species. A remote plasma can be used to produce reactive chemical species for processing a substrate that is located outside of the plasma. A remote plasma also can be used to produce reactive chemical species for cleaning processing chamber surfaces that are located outside of the plasma.

The term “silicon-containing precursor” generally represents any material that can be introduced into a processing chamber in a gas phase to form a film of a silicon-containing dielectric material on the substrate. Example silicon-containing precursors for forming silicon-containing dielectric material films using PEALD can comprise materials having the general structure:

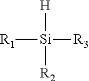

where R₁, R₂ and R₃ can be the same or different substituents. In various examples, R₁, R₂ and R₃ can include silanes, siloxy groups, amines, halides, hydrogen, or organic groups, such as alkylamines, alkoxy, alkyl, alkenyl, alkynyl, and cyclic groups (such as aromatic groups).

In some examples, the silicon-containing precursor is an alkoxysilane. Alkoxysilanes that can be used include compounds having a general structure of Hₓ—Si—(OR)_{y}, where x=1-3, x+y=4 and each R is a substituted or unsubstituted aliphatic or aromatic group; and Hₓ(RO)_{y}, —Si—Si—(OR)_{y}Hₓ, where each R is a substituted or unsubstituted aliphatic or aromatic group.

In some examples, the silicon-containing precursor is an aminosilane. Aminosilanes that can be used include materials having the general formula Hₓ—Si—(NR)_{y}, where x=1-3, x+y=4, and R is a substituted or unsubstituted alkyl, alkenyl, alkynyl or aromatic group or hydride group. Example aminosilanes include bisdiethylaminosilane, diisopropylaminosilane, bis(t-butylamino) silane (BTBAS), di-sec-butylaminosilane, and tris (dimethylamino) silane (3DMAS).

In some examples, the silicon-containing precursor is a halogen-containing silane. In some examples, a halogen-containing silane can comprise at least one hydrogen atom. Such a silane can have a chemical formula of SiXₐH_{y} where y≥1. Dichlorosilane (H₂SiCl₂) is an example halogen-containing silane.

More specific examples of silicon-containing precursors include polysilanes (SiₙH₂ₙ₊₂, where n≥1, such as silane, disilane, trisilane, and tetrasilane), trisilylamine, tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), trimethoxysilane (TMS or TriMOS), octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

The term “substrate” generally represents any object on which a film can be deposited.

The term “substrate support” generally represents any structure for supporting a substrate in a processing chamber. Examples comprise pedestals, electrostatic chuck pedestals, and showerhead pedestals used for backside deposition processes.

Trench features can be used to form various structures in an integrated circuit. For example, deep trench isolation (DTI) structures can be used to electrically isolate neighboring device components in an integrated circuit. DTI structures can be fabricated by first performing a directional etch to form a high aspect ratio gap in a substrate, and then filling the high aspect ratio gap with a dielectric gapfill material. As atomic layer deposition (ALD) allows for conformal layer-by-layer film growth within high aspect ratio features, ALD can be used to fill the high aspect ratio gap with the dielectric gapfill material. The high aspect ratio gap formed in a DTI fabrication process is referred to herein as a DTI feature. The DTI feature filled with a dielectric gapfill material is referred to as a DTI structure.

In some integrated circuit fabrication processes, a chemical mechanical planarization (CMP) process or suitable etch process can be performed on a wafer backside to access a device region of the substrate. Such processes can expose a DTI structure from the backside of the wafer. The dielectric gapfill material within the DTI structures that are exposed by such backside processing should be free of seams or voids. Any voids or seams in the dielectric gapfill material can lead to damage to the dielectric gapfill material during the CMP or etching process.

A DTI feature can be lined with a layer of polycrystalline (“polysilicon”). The grains of silicon in the polysilicon material can cause the wall of the DTI feature to have an uneven surface. This uneven surface can result in a first depth in the DTI feature being narrower than a second depth in the DTI feature, where the second depth is deeper within the DTI feature than the first depth, with reference to an opening of the DTI. This width profile as a function of depth can be referred to as a reentrant feature.

When a conformal ALD process is used to fill a DTI feature comprising a reentrant feature with a dielectric gapfill material, the growing conformal film of the dielectric gapfill material film can pinch off the DTI feature at the reentrant feature. This can block ALD precursors from reaching surfaces below the reentrant feature in the ALD cycles that follow the pinch-off. As a result, a void can form at locations in the DTI feature deeper than the reentrant feature.

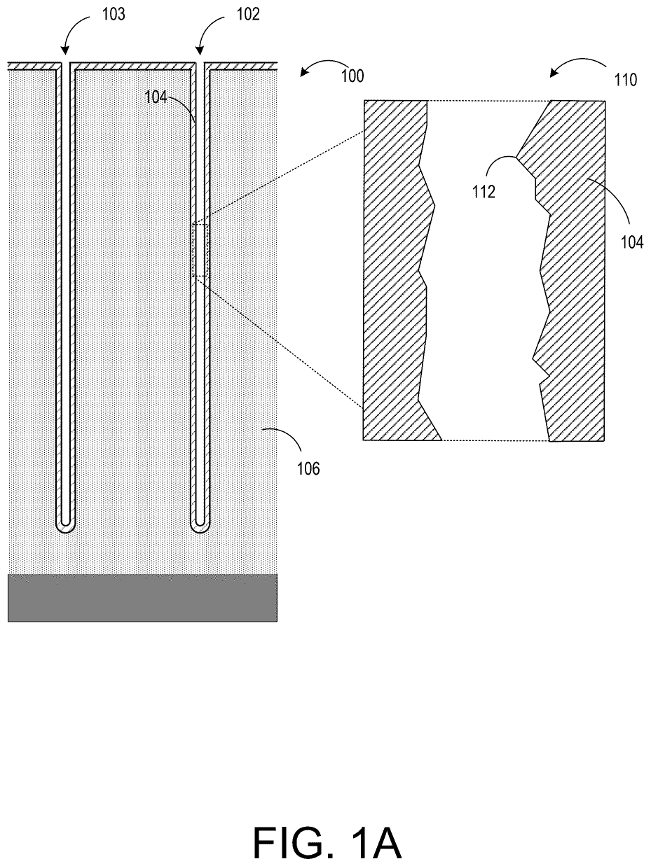

FIG. 1A shows a schematic depiction of a substrate 100 comprising example DTI features 102, 103. The DTI features 102, 103 each comprise a polysilicon layer 104 formed over a bulk silicon region 106 of the substrate 100. FIG. 1A also shows a magnified view 110 of a portion of the DTI feature 102. In the magnified view 110, it can be seen that the polysilicon layer 104 comprises local roughness. The local roughness forms reentrant features, such as reentrant feature 112.

FIG. 1B shows a magnified view 120 of a portion of the DTI feature 102 after performing a portion of a conformal dielectric gapfill material deposition process. A dielectric gapfill material layer 122 is deposited conformally on the polysilicon layer 104, including on reentrant feature 112. Next, FIG. 1C shows a magnified view 130 of a portion of the DTI feature 102 after continued conformal deposition of the dielectric gapfill material. Here, the dielectric gapfill material layer 122 has pinched off the DTI feature 102 at the reentrant feature 112. The pinching off of the DTI feature 102 at reentrant feature 112 causes a void 124 to form below the reentrant feature 112. Further, a void 126 also is formed above reentrant feature 112, due to another reentrant feature (not shown) located above reentrant feature 112. A seam can be formed from a chain of such voids extending along a portion of a depth of DTI feature 102. Such voids can be areas of weakness in a subsequent backside CMP or etching process.

A flowable silicon oxide can be used as a dielectric gapfill material to avoid the formation of voids or seams in a silicon oxide fill within a DTI feature. However, the quality of flowable silicon oxide can be poor and result in shrinkage and bubble formation.

Accordingly, examples are disclosed that relate to filling a DTI feature in a manner that can help to avoid the formation of voids. The disclosed examples use inhibited ALD processes. Briefly, an inhibited ALD process utilizes an inhibition cycle that deposits a first concentration of the inhibitor at a first depth within the DTI and a second concentration of inhibitor at a second depth within the DTI feature. The second depth is deeper within the DTI feature than the first depth. The term “deeper within the DTI feature” indicates that the second depth is farther from an opening of the DTI feature than the first depth. Further, the second concentration is less than the first concentration. After depositing the inhibitor, a plurality of atomic layer deposition (ALD) cycles are performed to fill the DTI feature with a dielectric gapfill material. One or more additional inhibition cycles can be performed between ALD cycles as needed. The inhibitor inhibits growth of the dielectric gapfill material such that the layer of the dielectric gapfill material grows at a higher rate at the second depth relative to the first depth. This allows the dielectric gapfill material to fill the DTI feature without forming a void. This can allow the DTI structure to be exposed by backside processing without damaging the gapfill within the DTI structure. While disclosed herein in the context of DTI features, any other suitable trench structure can be filled using inhibited ALD as disclosed herein.

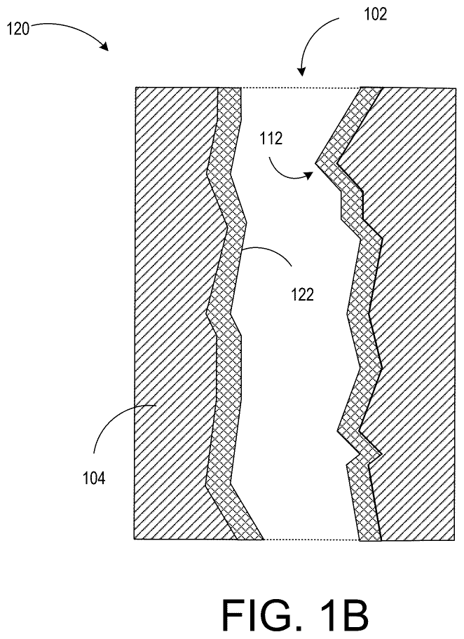

FIG. 2 shows a schematic view of an example processing tool 200 configured to perform an ALD process to deposit a dielectric gapfill material film using an inhibitor. Processing tool 200 comprises a processing chamber 202. Processing tool 200 further comprises a substrate support 204 within the processing chamber for supporting a substrate 206. Substrate support 204 can comprise a pedestal, a chuck, and/or any other suitable structure. Substrate support 204 further can include a substrate heater 208.

Processing tool 200 further comprises one or more processing gas inlets for introducing processing gases into processing chamber 202. One example processing gas inlet is shown a processing gas inlet 214 for admitting a flow of one or more processing gases.

In the depicted example, processing gas inlet 214 directs processes gases to a showerhead 210. In other examples, a nozzle and/or other suitable inlet hardware can be used. Processing tool 200 further comprises flow control hardware 216 for controlling the introduction of processing gases into processing chamber 202. Flow control hardware is connected to a dielectric gapfill material precursor source 218, an oxidant source 220, a passivation gas source 222, an inhibitor source 224, and a purge gas source 225. In some examples, the processing tool 200 can comprise a nitrogen source (not shown) for deposition of silicon oxynitride and/or silicon nitride. Example nitrogen sources can include a molecular nitrogen (N₂) source and/or an ammonia (NH₃) source.

The dielectric gapfill material precursor source 218 can comprise any suitable dielectric film precursor. In some examples, the dielectric gapfill material precursor source 218 comprises a silicon-containing precursor. As described above, example silicon-containing precursors for forming silicon-containing films using PEALD can comprise materials having the general structure:

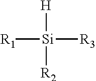

where R₁, R₂ and R₃ can be the same or different substituents. In various examples, R₁, R₂ and R₃ can include silanes, siloxy groups, amines, halides, hydrogen, or organic groups, such as alkylamines, alkoxy, alkyl, alkenyl, alkynyl, and cyclic groups (such as aromatic groups).

In some examples, the silicon-containing precursor is an alkoxysilane. Alkoxysilanes that can be used include compounds having a general structure of Hₓ—Si—(OR)_{y}, where x=1-3, x+y=4 and each R is a substituted or unsubstituted aliphatic or aromatic group; and Hₓ(RO)_{y}, —Si—Si—(OR)_{y}Hₓ, where each R is a substituted or unsubstituted aliphatic or aromatic group.

In some examples, the silicon-containing precursor is an aminosilane. Aminosilanes that can be used include materials having the general formula Hₓ—Si—(NR)_{y}, where x=1-3, x+y=4, and R is a substituted or unsubstituted alkyl, alkenyl, alkynyl or aromatic group or hydride group. Example aminosilanes include bisdiethylaminosilane, diisopropylaminosilane, bis(t-butylamino) silane (BTBAS), di-sec-butylaminosilane, and tris(dimethylamino) silane (3DMAS).

In some examples, the silicon-containing precursor is a halogen-containing silane. In some examples, a halogen-containing silane can comprise at least one hydrogen atom. Such a silane can have a chemical formula of SiXₐH_{y} where y≥1. Dichlorosilane (H₂SiCl₂) is an example halogen-containing silane.

More specific examples of silicon-containing precursors include polysilanes (SiₙH₂ₙ₊₂, where n≥1, such as silane, disilane, trisilane, and tetrasilane), trisilylamine, tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), trimethoxysilane (TMS or TriMOS), octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

The inhibitor source 224 can comprise any one or more of a fluorine-containing inhibitor, a carbon-containing inhibitor, or a nitrogen-containing inhibitor. Example fluorine-containing inhibitors can include one or more of F₂, NF₃, CF₄, SF₆, HF or XeF₂. Example nitrogen-containing inhibitors can include one or more of N₂, NH₃, amines, diamines or aminoalcohols. In some examples, an inhibitor can comprise H₂ mixed with another species, such as N₂. Example carbon-containing inhibitors can include one or more of an alkane, an alkene, an alkyne, a cyclic hydrocarbon, an alcohol, a diol, an aldehyde, an ester, an ether, a ketone, an alkyl halide, or an alkyl amine. More detailed examples of inhibitors are given above.

Oxidant source 220 can comprise any suitable oxidant that can oxidize a silicon-containing precursor adsorbed on the substrate during a dielectric gapfill material deposition cycle. Example oxidants comprise one or more of oxygen (O₂), ozone (O₃), one or more oxides of nitrogen (e.g. nitrous oxide (N₂O)), water vapor (H₂O), or hydrogen peroxide (H₂O₂). Further, as mentioned above, in some examples, an optional nitrogen source (not shown) can be included in some examples.

Passivation gas source 222 can comprise any suitable gas or gases to be used in a passivation cycle. Where a halogen-containing inhibitor or a nitrogen-containing inhibitor is used, example passivation cycles can remove inhibitor adsorbed to the substrate surface by exposing the inhibitor to one or more of H₂ or O₂. In some examples, thermal and/or plasma energy can be used to facilitate the passivation. Another example passivation involves exposing the inhibitor to a plasma comprising H₂/N₂/Ar. The passivation gas source 222 can include any one or more of such gases.

Purge gas source 225 can comprise any suitable inert gas. Examples include argon and nitrogen. In some examples, one or more additional purge gas sources can be included, each providing a different purge gas.

Processing tool 200 further comprises an exhaust system 234. Exhaust system 234 is configured to remove gases from processing chamber 202. Exhaust system 234 can comprise any suitable hardware. Example hardware includes one or more low vacuum pumps and/or one or more high vacuum pumps.

Substrate heater 208 can be used to provide thermal energy to facilitate an ALD process. In other examples, a plasma alternatively or additionally can be used to facilitate an ALD process. A plasma can be generated inside processing chamber 202 using a matching network A 230A and a radiofrequency (RF) power source A 232A. The plasma can provide the energy to generate chemically active species in the gas phase, thereby forming reactive chemical species. In other examples, a remote plasma generator 228 alternatively or additionally can be used to provide reactive chemical species for one or more of an ALD process, an inhibition cycle or a passivation cycle. Reactive chemical species from the remote plasma generator 228 can be introduced into the processing chamber 202 through a gas inlet 231. In other examples, the optional remote plasma generator 228 can be configured to introduce reactive chemical species into processing chamber 202 through the showerhead 210. Where the optional remote plasma generator 228 is used, the processing tool 200 further comprises a radiofrequency power source B 232B electrically connected to remote plasma generator 228, and a matching network B 230B for impedance matching of the radiofrequency power source B 232B.

The radiofrequency power source A 232A and the radiofrequency power source B 232B can be configured for any suitable frequency and power. Examples of suitable frequencies include 400 kHz, 13.56 MHz, 27 MHz, 60 Mz, and 90 MHz. Examples of suitable powers include powers between 50 W (watts) and 50 kW. In some examples, radiofrequency power source A 232A and radiofrequency power source B 232B can be configured to operate at a plurality of different frequencies and/or powers.

The flow control hardware 216 can be controlled to flow processing chemicals from the dielectric gapfill precursor source 218, oxidant source 220, passivation gas source 222, inhibitor source 224, and purge gas source 225 into the processing chamber 202 through processing gas inlet 214. In some examples, flow control hardware 216 also can be configured to control the flow of one or more chemicals into the remote plasma generator 228. The flow control hardware 216 schematically represents any suitable components related to flowing gas into processing chamber 202 (and remote plasma generator 228 in some examples). For example, the flow control hardware 216 can comprise one or more mass flow controllers and/or valves controllable to place a selected chemical source in fluid connection with the processing chamber 202.

A controller 236 is operatively coupled to the substrate heater 208, the flow control hardware 216, the remote plasma generator 228, the exhaust system 234, the radiofrequency power source A 232A, and the radiofrequency power source B 232B. The controller 236 further can be operatively coupled to any other suitable component of the processing tool 200. The controller 236 is configured to control various functions of processing tool 200 to perform an inhibited ALD process.

For example, the controller 236 is configured to operate the substrate heater 208 to heat a substrate. The controller 236 is also configured to operate the flow control hardware 216 to flow a selected chemical or mixture of chemicals at a selected rate into the processing chamber 202. The controller 236 is also configured to operate the exhaust system 234 to remove gases from the processing chamber 202. The controller 236 is further configured to operate the flow control hardware 216 and the exhaust system 234 to maintain a selected pressure within the processing chamber 202. The controller 236 is further configured to control the radiofrequency power source A 232A to control the plasma generated in the chamber. Furthermore, the controller 236 is configured to operate the optional radiofrequency power source B 232B to form a remote plasma.

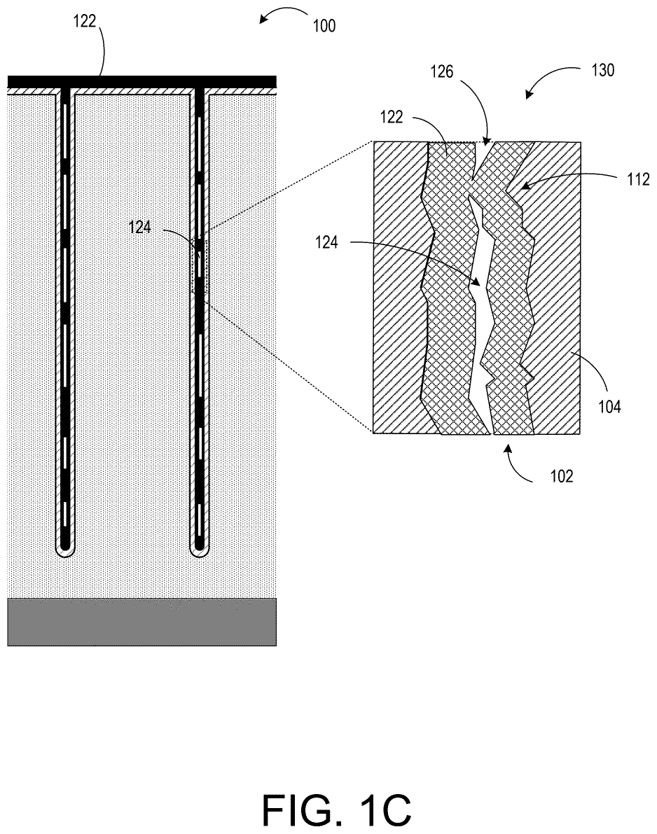

FIGS. 3A-3B show a flow diagram illustrating an example method 300 for filling DTI features in a bottom-up manner using an inhibited ALD process. First referring to FIG. 3A, the method 300 comprises, at step 302, performing an inhibition cycle. The inhibition cycle comprises depositing an inhibitor on the substrate under conditions that deposit a greater concentration of the inhibitor at a first depth within the DTI than at a second depth within the DTI feature. The second depth is deeper within the DTI feature than the first depth. The greater the concentration of the inhibitor, the slower the dielectric gapfill material film growth.

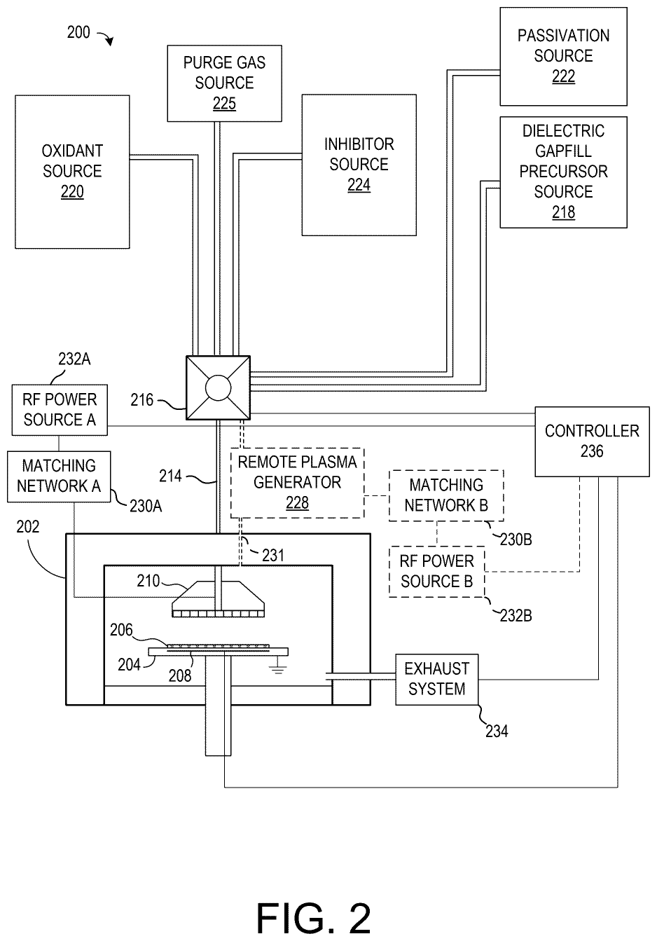

FIG. 4A shows a schematic depiction of a substrate 400 comprising DTI features 402, 403 that are similar to the DTI features 102, 103 in FIG. 1A. The DTI features 402, 403 each comprises a polysilicon layer 404 formed over a bulk silicon region 406 of the substrate 400. FIG. 4A also shows a magnified view 410 of a portion of the DTI feature 402. In the magnified view 410, it can be seen that the polysilicon layer comprises local roughness. The local roughness forms reentrant features, such as reentrant feature 412. Example reentrant features can comprise slits, holes, rings, 3-way street structures, and 4-way street structures. Such structures can have critical dimensions within a range of 0.01-0.25 μm in some examples.

FIG. 4B shows that the inhibitor 414 is deposited under conditions such that a first concentration of the inhibitor at a first depth 420 in the DTI feature 402 is higher than a second concentration of the inhibitor at a second depth 422 in the DTI feature, where the second depth 422 is deeper within the DTI feature than the first depth 420. The resulting inhibitor concentration gradient allows a dielectric gapfill material film to grow at a higher rate at the second depth 422 relative to the first depth 420. This can help to achieve a bottom-up gapfill in the DTI feature without forming voids.

In some examples, the inhibitor comprises a halogen-containing inhibitor, as shown at 304. Inhibitors can physisorb and/or chemisorb on substrate surfaces in various examples. For example, halogen-containing inhibitors can chemisorb on substrate surfaces. More particularly, a plasma deposition process can be used to deposit a halogen-containing inhibitor. The plasma creates reactive halogen species from the halogen-containing inhibitor. In the example of a silicon-oxygen containing dielectric gapfill material, the reactive halogen species react with hydroxyl (OH) groups on the material surface to replace the H and form a halogen-terminated surface. Examples of halogen-containing inhibitors can include fluorine-containing inhibitors, as indicated at 306. Examples of halogen-containing inhibitors also can include chlorine-containing inhibitors, bromine-containing inhibitors, and iodine-containing inhibitors. Examples of fluorine-containing inhibitors can include molecular fluorine (F₂), hydrogen fluoride (HF), boron trifluoride (BF₃), phosphorus trifluoride (PF₃), nitrogen trifluoride (NF₃), chlorine trifluoride (ClF₃), chlorine pentafluoride (ClF₅), sulfur tetrafluoride (SF₄), and sulfur hexafluoride (SF₆). Further examples of fluorine-containing inhibitors can include chalcogen fluorides such as selenium tetrafluoride (SeF₄), selenium hexafluoride (SeF₆), and tellurium hexafluoride (TeF₆). Further examples of fluorine-containing inhibitors can include chlorofluorocarbons such as trichlorofluoromethane (CCl₃F), fluorocarbons such as carbon tetrafluoride (CF₄) or hexafluoroethane (C₂F₆), and hydrofluorocarbons such as difluoromethane (CH₂F₂). Further examples of halogen-containing inhibitors can include chlorine (Cl₂), hydrogen chloride (HCl), carbon tetrachloride (CCl₄), bromine (Br₂), hydrogen bromide (HBr), iodine (I₂), hydrogen iodide (HI), and 1,2-diiodoethane (C₂H₄I₂).

In other examples, the inhibitor comprises a nitrogen-containing inhibitor, as shown at 308. Nitrogen-containing inhibitors also can chemisorb on substrate surfaces. For example, nitrogen-containing inhibitors can be deposited by plasma to form reactive nitrogen species that react with —OH groups on a silicon oxide dielectric gapfill material surface to bond to the silicon oxide surface. Example nitrogen-containing comprises one or more of nitrogen, ammonia, an amine, a diamine, or an aminoalcohol, as shown at 310.

In yet other examples, the inhibitor comprises a carbon-containing inhibitor, as shown at 312. Carbon-containing inhibitors can primarily physisorb on substrate surfaces. Carbon-containing inhibitors compete with silicon-containing precursors or other dielectric gapfill material precursors for oxygen. Thus, carbon-containing precursors reduce the amount of oxygen that is available for oxidation of dielectric gapfill material precursors. This slows the rate of dielectric gapfill material film growth. Example carbon-containing comprises one or more of an alkane, an alkene, an alkyne, a cyclic hydrocarbon, an alcohol, a diol, an aldehyde, an ester, an ether, a ketone, an alkyl halide, or an alkyl amine as shown at 314. Any suitable carbon-containing inhibitor can be used. In some examples, the carbon-containing inhibitor can comprise an alkane comprising a general formula CₙH₂ₙ₊₂ in which n=1 to 10. Examples of suitable alkanes can include methane, ethane, propane, butane, pentane, hexane, and substituted alkanes. Other examples of carbon-containing inhibitors can comprise an alkene, an alkyne, a cyclic hydrocarbon, an aromatic, an alcohol, a diol, an aldehyde, an ester, an ether, a ketone, an alkyl halide, or an alkyl amine. In still other examples, the carbon-containing inhibitor can comprise a mixture of carbon-containing inhibitors. Examples of suitable alkenes (CₙH₂ₙ in which n=2 to 10, for an alkene with a single carbon-carbon double bond) can include ethene, propene, and butene. Examples of suitable alkynes (CₙH₂ₙ₋₂ in which n=2 to 10, for an alkyne with a single carbon-carbon triple bond) can include acetylene, propyne, and butyne. Examples of suitable cyclic hydrocarbons can include cyclobutane, cyclopentane and cyclohexane. Examples of suitable aromatics can include benzene, toluene, pyridine, and pyrimidine. Examples of suitable alcohols can include methanol, ethanol, and propanol. Examples of suitable diols can include ethylene glycol, propylene glycol, and hydroquinone. Examples of suitable aldehydes can include formaldehyde and acetaldehyde. Examples of suitable esters can include ethyl formate, methyl acetate, and ethyl acetate. Examples of suitable ethers can include diethyl ether, methyl phenyl ether, and aromatic ethers such as furan. Examples of suitable ketones can include acetone and methyl ethyl ketone. Examples of suitable alkyl halides can include ethyl fluoride, isopropyl bromide, and t-butyl chloride. Examples of suitable alkyl amines can include methylamine, dimethylamine, trimethylamine, piperidine, ethylenediamine and 1,3-diaminopropane. Suitable carbon-containing inhibitors also can include substituted variants of such molecules.

The deposition of the inhibitor to form a concentration gradient of inhibitor within the DTI feature can be controlled by controlling various processing conditions used in an inhibition cycle. Example processing conditions include total processing chamber pressure, partial pressure of the inhibitor, partial pressure of other gases (for example, a diluent gas), substrate temperature, gas flow rates, inhibitor gas flow duration, and/or plasma characteristics. For example, the use of an in-situ plasma to deposit inhibitor can cause directional effects that drive the inhibitor into a gap. In some examples, the in-situ plasma can comprise a higher frequency component and a lower frequency component. The higher frequency component can provide the activation energy to form reactive inhibitor species. The lower frequency component can be used to direct the reactive inhibitor species into the DTI feature.

In some examples, the higher frequency radiofrequency energy component can comprise a power in a range of 50-6000 W. Increasing the power of the higher frequency component can drive the inhibitor farther within the gap. The lower frequency RF energy component also can comprise a power in a range of 0-6500 W. Increasing the power of the lower frequency component also can used to drive inhibitor farther within the gap. Increasing the inhibition time, the inhibitor partial pressure, the total processing chamber pressure, and the inhibitor flow rate can also lead to more inhibitor deposited deeper within the gap.

In some examples, a silicon oxide liner can be deposited using a thermal atomic layer deposition (TALD) process prior to performing an inhibition cycle, as indicated at step 316. The silicon oxide liner acts a protective layer to prevent the oxidation of the underlying polysilicon during the gapfill deposition process. The TALD process conditions can be controlled to prevent or minimize the oxidation of the underlying polysilicon surface.

Continuing with FIG. 3B, the method 300 comprises, at step 318, performing a plurality of dielectric gapfill material atomic layer deposition (ALD) cycles to fill the DTI feature with dielectric gapfill material. The deposited inhibitor inhibits growth of the dielectric gapfill material such that the layer of the dielectric gapfill material grows at a higher rate at the second depth relative to the first depth to fill the DTI feature without forming a void. In some examples, PEALD can be used to perform the dielectric gapfill material ALD cycles. In some such examples, RPEALD can be used. In other examples, TALD can be used to perform the dielectric gapfill material ALD cycles.

FIG. 4C shows that the greater concentration of the inhibitor 414 closer to the opening of the DTI feature inhibits dielectric gapfill material deposition at the first depth 420. However, dielectric gapfill material 424 is deposited at the second depth 422. In this manner, DTI feature 402 is progressively filled by dielectric gapfill material ALD cycles without pinching off at reentrant feature 412. FIG. 4D shows that the DTI features 402, 403 are completely filled with dielectric gapfill material 424 without the formation of seams or voids. This is shown in greater detail in the magnified view at 430.

In some examples, one or more additional inhibition cycles can be performed between dielectric gapfill material deposition cycles, as shown at step 320 of FIG. 3B. Whether to perform additional inhibition cycles can depend upon a profile of a DTI feature being filled, an inhibitor being used, and a dielectric gapfill material being deposited.

In some examples, a passivation cycle can be performed to remove at least some of the inhibitor from the substrate, as shown at step 322 in FIG. 3B. In some examples, a passivation cycle can be performed between dielectric gapfill material ALD cycles before performing an inhibition cycle. In other examples, a passivation cycle can be performed after the dielectric gapfill material deposition process is complete, to remove inhibitor from regions of a substrate surface between openings of DTI features. As another example, after filling a first region of within a DTI feature with dielectric gapfill material, a passivation step can be performed to remove the inhibitor from a second region within the DTI feature to facilitate the deposition of dielectric gapfill material at the opening of the DTI feature, wherein the second region is less deep than the first region.

By performing a bottom-up gapfill using one or more inhibition cycles, a DTI feature can be filled with dielectric gapfill material without forming seams or voids. Thus, continuing with FIG. 3B, backside processing to reveal DTI structures can be performed at step 324 without damaging the dielectric gapfill material within the DTI structures. In some examples, the backside processing can include chemical mechanical planarization, as indicated at step 326. Alternatively or additionally, the backside processing can include etching.

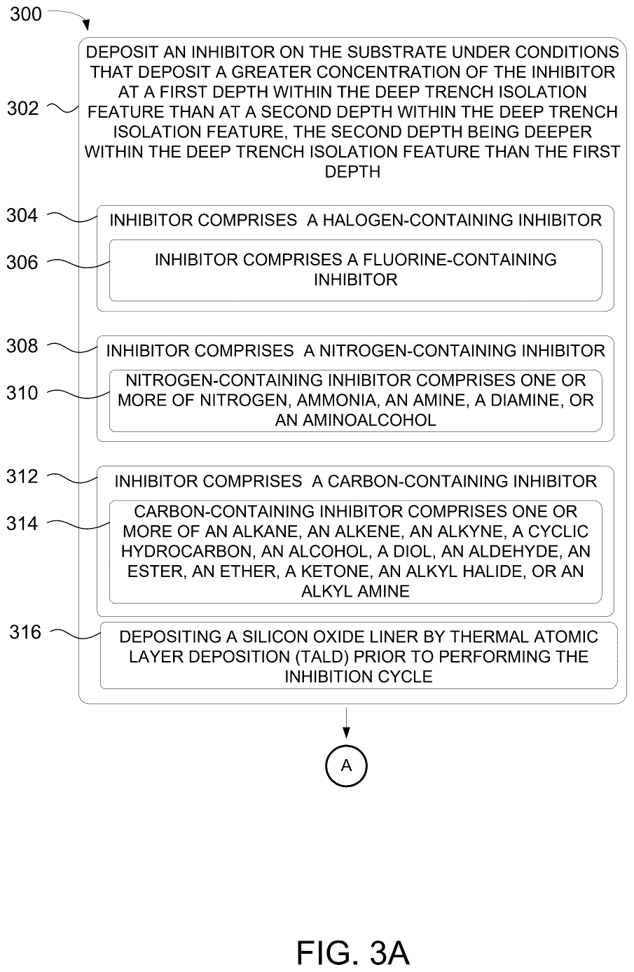

The passivation cycles, dielectric gapfill material deposition cycles, and inhibition cycles can be performed in various permutations and combinations. A selected DTI feature gapfill process can depend on factors such as the substrate, choice of inhibitor, choice of dielectric gapfill material, and deposition conditions. In some examples, processing times and throughput can also be a factor. FIGS. 5-11 show various examples of permutations of inhibition, dielectric gapfill material deposition, and passivation cycles.

First, FIG. 5 shows a flow diagram depicting an example method 500 for performing ALD dielectric gapfill material deposition with an inhibition cycle 502 and a passivation cycle 506. Method 500 comprises an inhibition cycle 502 and X number of ALD cycles 504 to help achieve nonconformal dielectric gapfill material film deposition. X represents an integer greater than or equal to one. The inhibition cycle 502 can comprise introduction of any suitable inhibitor. Examples include a nitrogen-containing inhibitor, a fluorine-containing inhibitor, or a carbon-containing inhibitor. In some examples, an inhibitor can comprise H₂ mixed with another species, such as N₂. More detailed examples of inhibitors are given above. The inhibition cycle deposits a relatively greater concentration closer to the opening of the DTI feature than deeper within the DTI feature.

The inhibitor can be deposited using a PEALD process in the inhibition cycle 502. The PEALD process can comprise a higher frequency energy component and a lower frequency energy component in some examples. In some examples, the higher frequency RF energy component can be varied in the range of 50-1500 W. Increasing the energy of the higher frequency component can lead to stronger inhibition. The lower frequency component can be used to direct the inhibitor to the substrate. The lower frequency RF energy component can be varied in the range of 0-1500 W in some examples. Increasing the energy of the lower frequency component can lead to stronger inhibition. Increasing the inhibition time, the inhibitor partial pressure and the inhibitor flow rate can also lead to stronger inhibition. In some examples, the inhibition time can comprise a time within a range of 0.1-30 s. Further, in some examples, the inhibitor flow rate can comprise a flow within a range of 5-250 standard cubic centimeters per minute (sccm). In other examples, one or more suitable values outside of the stated ranges can be used for one or more of the above-described parameters.

At 504, method 500 performs X number of ALD cycles. Any suitable number X of ALD cycles can be performed at 504. After performing an inhibition cycle at 502 and X number of ALD cycles at 504, method 500 comprises performing a passivation cycle at 506. As described above, a passivation cycle can be performed to remove residual inhibitor from the substrate. Where a halogen-containing inhibitor or a nitrogen-containing inhibitor is used, example passivation cycles can comprise exposing the inhibitor adsorbed to the substrate surface to one or more of H₂ or O₂. In some examples, thermal and/or plasma energy can be used to facilitate the passivation. Another example passivation involves exposing the inhibitor to a plasma comprising H₂/N₂/Ar. In other examples, the inhibitor can be consumed over the course of the ALD process. The inhibition cycle performed at 502, the ALD cycle(s) performed at 504, and the passivation cycle performed at 506 can be repeated any suitable number Y of times, as indicated at 508. Y is an integer greater than or equal to zero. Thus, method 500 includes one passivation cycle for X number of ALD cycles. A greater ratio of ALD cycles to inhibition cycles can result in a greater degree of conformality of the dielectric gapfill material film. The degree of conformality of the dielectric gapfill material film deposition can thus be controlled by adjusting the ratio of ALD cycles to inhibition cycles. This applies to methods 500, 600, 700, 800, 900, 1000, and 1100. Once a target dielectric gapfill material film has been deposited, method 500 can terminate.

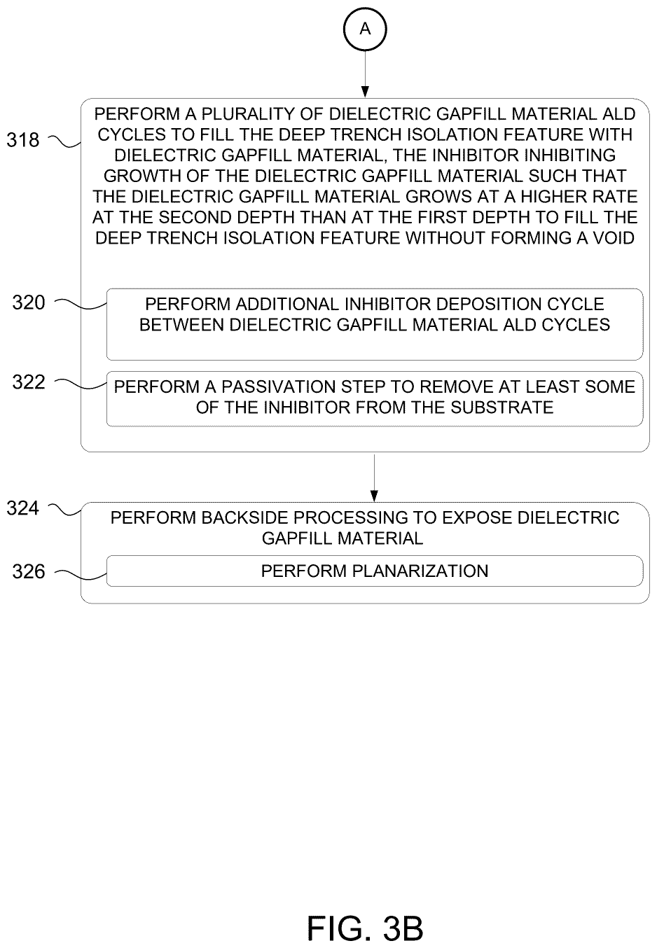

In some examples, passivation can be performed at different intervals than inhibition. FIG. 6 shows an example method 600 for performing a sequence that comprises a subcycle comprising an inhibition cycle 602 and X number of ALD cycles 604. The subcycle is performed Y times as indicated at 608, and then Z number of passivation cycles 606 is performed. The numbers X, Y and Z independently each can be an integer equal to or greater than one.

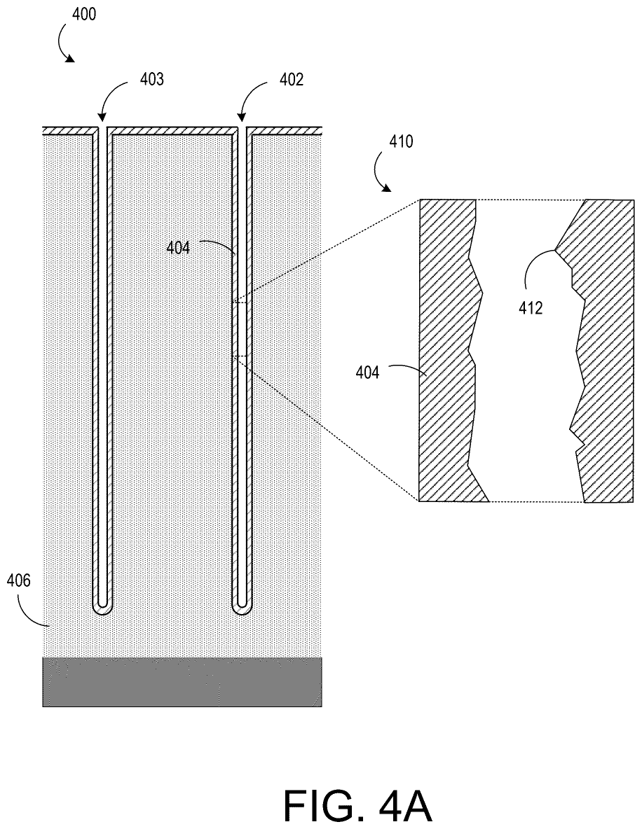

In some examples, an inhibitor can be removed by the dielectric gapfill material deposition process. In such examples, a passivation cycle can be omitted. FIG. 7 shows a flow diagram of an example method 700 comprising an inhibition cycle 702 and X number of ALD cycles 704 performed Y times, as indicated at 706. Method 700 omits a passivation cycle. As one example, carbon can be oxidized along with the adsorbed silicon-containing species during the oxidation cycle of a dielectric gapfill material deposition. The numbers X and Y independently each can be an integer equal to or greater than one.

A greater ratio of ALD cycles to inhibition cycles can result in a greater degree of conformality of the dielectric gapfill material film. The degree of conformality of the dielectric gapfill material film can thus be controlled by adjusting the ratio of ALD cycles to inhibition cycles. Once a target film has been achieved, method 700 can terminate.

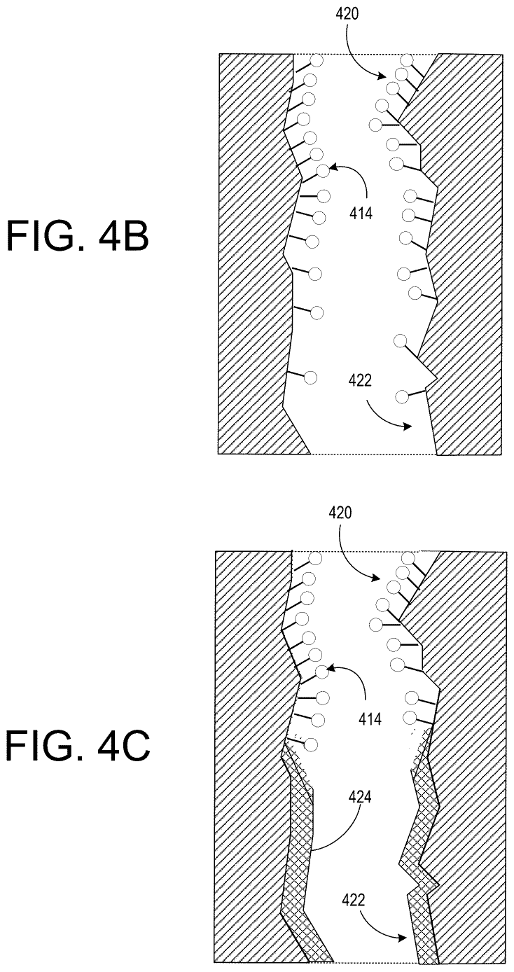

In some examples, a single passivation cycle can be performed at the end of the dielectric gapfill deposition process. FIG. 8 shows an example method 800 for performing inhibited ALD with a final passivation cycle.

Method 800 comprises performing an inhibition cycle 802 followed by X number of ALD cycles 804. This is repeated Y times, as indicated at 808. The numbers X and Y independently each can be an integer equal to or greater than one. A greater ratio of ALD cycles to inhibition cycles can result in a greater degree of conformality of the dielectric gapfill material film. The degree of conformality of the dielectric gapfill material film deposition can thus be controlled.

Once a target dielectric gapfill material film has been deposited, method 800 can proceed to 806 and perform a passivation cycle. After performing the passivation cycle at 806, method 800 can terminate.

Various process variables can be adjusted to affect a degree of film conformality. As described above, a ratio of ALD cycles to inhibition cycles can be adjusted to control a degree of nonconformal growth. As another example, varying a time of exposure to the inhibitor can vary the conformality of the dielectric gapfill material film. For example, longer inhibitor exposure times can generate more conformity than shorter inhibitor exposure times, as longer inhibitor exposure times can allow a concentration of inhibitor to reach more equal levels at all depths within a DTI feature. Other processing conditions that can affect a concentration gradient of inhibitor within a DTI feature are described in more detail above.

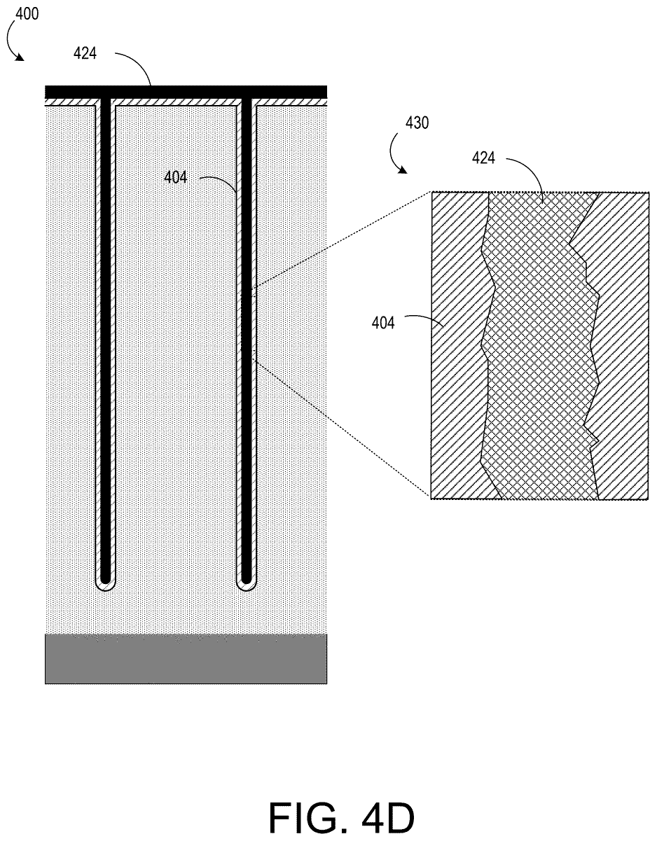

In some examples, an inhibition cycle, an ALD deposition cycle and a passivation cycle can be performed at one more of a same pressure or a same gas flow rate. FIG. 9 shows an example method 900 for performing ALD processing with an inhibition cycle 902 and a passivation cycle 912 that can be performed at one or more of a same pressure and/or gas flow rate. Method 900 comprises an inhibition cycle 902, a dose cycle 904, a purge cycle 906, an oxidation cycle 908 and another purge cycle 910. These cycles are repeated X number of times. The number X comprises an integer greater than or equal to one.

The dose cycle 904 comprises flowing a dielectric gapfill material precursor over the substrate. Examples of dielectric gapfill material precursors include those listed above. Excess dielectric gapfill material precursor is purged during the purge cycle 906. Example purge gases include argon and nitrogen. In some examples, a plurality of purge gases can be used.

The oxidation cycle at 908 comprises introducing an oxidant to oxidize the physisorbed and/or chemisorbed dielectric gapfill material precursor to form. Any suitable oxidant can be used. Example oxidants comprise one or more of oxygen (O₂), ozone (O₃), one or more oxides of nitrogen (e.g. nitrous oxide (N₂O)), water vapor (H₂O), or hydrogen peroxide (H₂O₂). Further, molecular nitrogen, ammonia, and/or another nitrogen source can be used to form nitride and/or oxynitride dielectric gapfill films. In examples that utilize PEALD, a plasma is used to facilitate oxidation. In some examples, the substrate is heated to a temperature within a range of 150 °C to 650 °C. during PEALD processing. In examples that utilize TALD, heat is used to facilitate oxidation in the absence of a plasma.

Byproducts and excess oxidants from the oxidation cycle are removed by another purge cycle 910. The purge cycle 910 comprises flowing a purge gas through the system. Example purge gases are described above.

After performing processes 904-910 X times, method 900 comprises performing Y number of cycles of passivation, where Y is an integer greater than or equal to one. After Y number of cycles of passivation, inhibition 902 and ALD deposition processes 904-910 can be performed again if desired. Once a target dielectric gapfill film has been achieved, method 900 terminates.

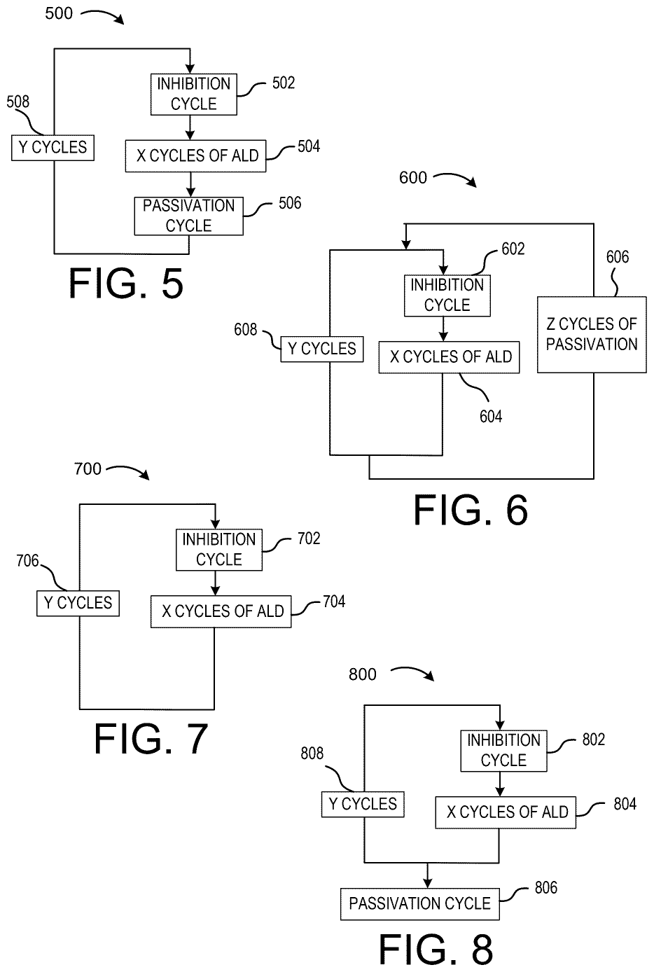

FIG. 10 shows another example method 1000 for performing inhibited ALD in which inhibition and deposition steps can be performed at a same pressure and/or gas flow rate. Method 1000 omits a passivation cycle. Thus, method 1000 can be suitable for use with an inhibitor such as carbon that is removed during an oxidation cycle. Method 1000 comprises performing an inhibition cycle 1002. Method 1000 further comprises performing a dielectric gapfill material deposition using an ALD process. The ALD process comprises a dose cycle 1004, a purge cycle 1006, an oxidation cycle 1008 and another purge cycle 1010. These cycles can be performed as described above with regard to FIG. 9. Dose cycle 1004, purge cycle 1006, oxidation cycle 1008 and purge cycle 1010 can be repeated X number of times, as indicated at 1014, where X is an integer greater than or equal to one. Further, after X number of cycles, method 1000 can again perform an inhibition cycle at 1002. Cycle 1012, followed by X number of cycles of 1002-1014 can be repeated Y times, wherein Y is an integer greater than or equal to one.

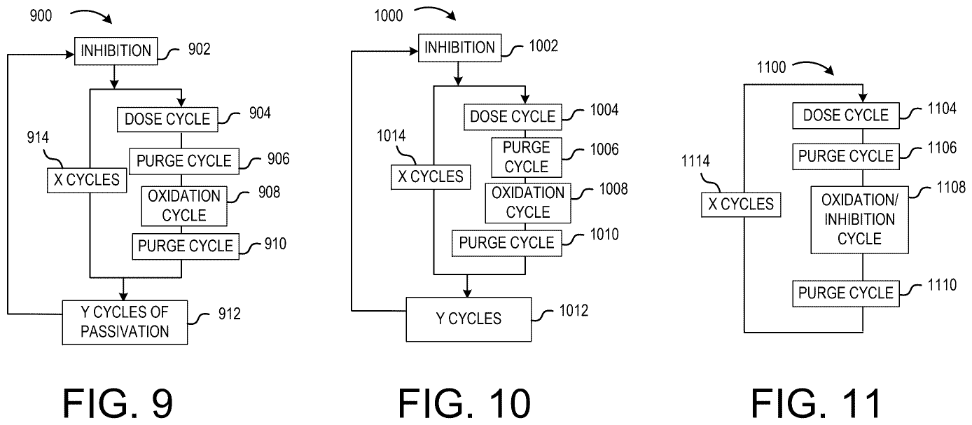

FIG. 11 shows another example method 1100 for performing inhibited ALD in which inhibition, ALD deposition and passivation can be performed at a same pressure and/or gas flow rate. In method 1100, inhibition and oxidation are performed in a same step. Method 1100 comprises a dose cycle 1104 and a purge cycle 1106, as described above. Method 1100 next comprises an oxidation and inhibition cycle 1108, followed by another purge cycle 1110.

In the oxidation and inhibition cycle 1108, an oxidant and an inhibitor are introduced. The oxidant oxidizes the dielectric gapfill material precursor introduced in dose cycle 1104. The inhibitor can comprise one or more of a fluorine-containing inhibitor, a carbon-containing inhibitor, or a nitrogen-containing inhibitor. In some examples, an inhibitor can comprise H₂ mixed with another species, such as N₂. In some examples, the inhibitor can be deposited on the substrate using a plasma that is also used to oxidize the dielectric gapfill material precursor.

Any byproducts formed during the oxidation cycle, excess inhibitor and excess oxygen can be removed from the system during the purge cycle 1110. This can comprise flowing a purge gas through the system. A purge gas can comprise any suitable inert gas or gases.

Continuing X number of ALD cycles can be performed as indicated at 1114. Any suitable number X of ALD cycles can be performed at 1114. Once a sufficient dielectric gapfill material film thickness has been achieved, method 1100 can terminate. In some examples, the substrate is heated using a substrate heater during processing. In some examples, the substrate heater can be heated to a temperature within a range of 150 °C to 650 °C. In other examples, a temperature outside of this range can be used. The different steps of the ALD process can generally be performed at the same temperature. By performing a combined inhibition/oxidation, an overall processing time can be reduced. This can lead to higher throughput.

In some examples, the methods and processes described herein can be tied to a computing system of one or more computing devices. In particular, such methods and processes can be implemented as a computer-application program or service, an application-programming interface (API), a library, and/or other computer-program product.

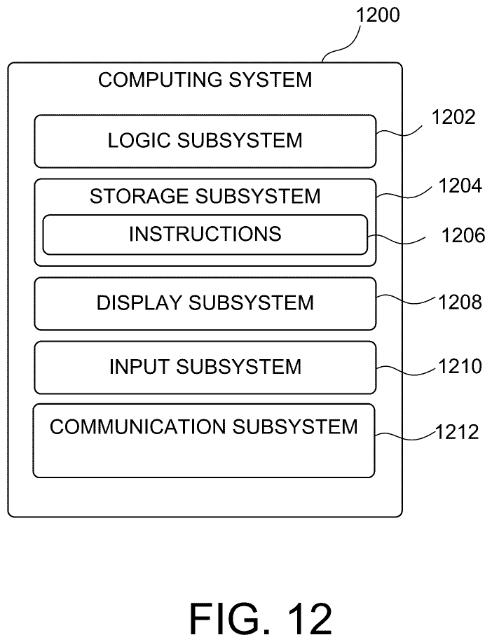

FIG. 12 schematically shows an example of a computing system 1200 that can enact one or more of the methods and processes described above. Computing system 1200 is shown in simplified form. Computing system 1200 can take the form of one or more personal computers, server computers, tablet computers, network computing devices, and/or other computing devices. Controller 236 in FIG. 2 is an example of computing system 1200.

Computing system 1200 includes a logic subsystem 1202 and a storage subsystem 1204. Computing system 1200 can optionally include a display subsystem 1208, input subsystem 1210, communication subsystem 1212, and/or other components not shown in FIG. 12.

Logic subsystem 1202 includes one or more physical devices configured to execute instructions 1206. For example, the logic subsystem can be configured to execute instructions that are part of one or more applications, services, programs, routines, libraries, objects, components, data structures, or other logical constructs. Such instructions can be implemented to perform a task, implement a data type, transform the state of one or more components, achieve a technical effect, or otherwise arrive at a desired result. As examples, logic subsystem can execute instructions to implement method 300 on a processing tool.

The logic subsystem can include one or more processors configured to execute software instructions. Additionally or alternatively, the logic subsystem can include one or more hardware or firmware logic devices configured to execute hardware or firmware instructions. Processors of the logic subsystem can be single-core or multi-core, and the instructions executed thereon can be configured for sequential, parallel, and/or distributed processing. Individual components of the logic subsystem optionally can be distributed among two or more separate devices, which can be remotely located and/or configured for coordinated processing. Aspects of the logic subsystem can be virtualized and executed by remotely accessible, networked computing devices configured in a cloud-computing configuration.

Storage subsystem 1204 includes one or more physical devices configured to hold instructions 1206 executable by the logic subsystem to implement the methods and processes described herein. For example, storage subsystem 1204 can comprise instructions executable to perform the methods of FIGS. 3A-3B and 5-11.

Storage subsystem 1204 can include removable and/or built-in devices. Storage subsystem 1204 can include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage subsystem 1204 can include volatile, nonvolatile, dynamic, static, read/write, read-only, random-access, sequential-access, location-addressable, file-addressable, and/or content-addressable devices.

It will be appreciated that storage subsystem 1204 includes one or more physical devices. However, aspects of the instructions described herein alternatively can be propagated by a communication medium (e.g., an electromagnetic signal, an optical signal, etc.) that is not held by a physical device for a finite duration.

Aspects of logic subsystem 1202 and storage subsystem 1204 can be integrated together into one or more hardware-logic components. Such hardware-logic components can include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 1208 can be used to present a visual representation of data held by storage subsystem 1204. This visual representation can take the form of a graphical user interface (GUI). As the herein described methods and processes change the data held by the storage subsystem, and thus transform the state of the storage subsystem, the state of display subsystem 1208 can likewise be transformed to visually represent changes in the underlying data. Display subsystem 1208 can include one or more display devices utilizing virtually any type of technology. Such display devices can be combined with logic subsystem 1202 and/or storage subsystem 1204 in a shared enclosure, or such display devices can be peripheral display devices.

When included, input subsystem 1210 can comprise or interface with one or more user-input devices such as a keyboard, mouse, or touch screen. In some examples, the input subsystem can comprise or interface with selected natural user input (NUI) componentry. Such componentry can be integrated or peripheral, and the transduction and/or processing of input actions can be handled on- or off-board.

When included, communication subsystem 1212 can be configured to communicatively couple computing system 1200 with one or more other computing devices. Communication subsystem 1212 can include wired and/or wireless communication devices compatible with one or more different communication protocols. As examples, the communication subsystem can be configured for communication using a wireless telephone network, or a wired or wireless local- or wide-area network. In some examples, the communication subsystem can allow computing system 1200 to send and/or receive messages to and/or from other devices using a network such as the Internet.

It will be understood that the configurations and/or approaches described herein are exemplary in nature, and that these specific examples or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of processing a substrate comprising a trench feature, the trench feature comprising a polysilicon surface, the polysilicon surface comprising reentrant features, the method comprising:
performing an inhibition cycle comprising depositing an inhibitor on the substrate under conditions that deposit a greater concentration of the inhibitor at a first depth within the trench feature than at a second depth within the trench feature, the second depth being deeper within the trench feature than the first depth; and
performing a plurality of atomic layer deposition (ALD) cycles to fill the trench feature with a dielectric gapfill material, the inhibitor inhibiting growth of the dielectric gapfill material such that a layer of the dielectric gapfill material grows at a higher rate at the second depth relative to the first depth to fill the trench feature.

2. The method of claim 1, wherein the trench feature is filled without forming a void.

3. The method of claim 1, wherein the inhibitor comprises a halogen-containing inhibitor.

4. The method of claim 1, wherein the inhibitor comprises a nitrogen-containing inhibitor.

5. The method of claim 1, wherein the inhibitor comprises a carbon-containing inhibitor.

6. The method of claim 1, wherein the dielectric gapfill material comprises silicon dioxide.

7. The method of claim 1, wherein the dielectric gapfill material comprises silicon nitride, silicon oxynitride, or silicon oxycarbide.

8. The method of claim 1, further comprising performing an additional inhibition cycle between atomic layer deposition cycles of the plurality of atomic layer deposition cycles.

9. The method of claim 1, further comprising depositing a silicon oxide liner by thermal atomic layer deposition (TALD) prior to performing the inhibition cycle.

10. The method of claim 1, further comprising a passivation step to remove at least some of the inhibitor from the substrate.

11. The method of claim 1, wherein the trench feature comprises one or more of a slit, a hole, a ring, a 3-way street or a 4-way street structure.

12. An atomic layer deposition (ALD) tool, comprising:
a processing chamber;
a dielectric gap fill material precursor source comprising a dielectric gapfill material precursor;
a reactant source comprising a reactant;
an inhibitor source comprising an inhibitor;
flow control hardware fluidly connecting the dielectric gapfill material precursor source, the reactant source, and the inhibitor source to the processing chamber;
a controller configured to control the atomic layer deposition tool to:
operate the flow control hardware to perform an inhibition cycle in which the inhibitor is introduced into the processing chamber under conditions selected to deposit a greater concentration of the inhibitor at a first depth within a trench feature on a substrate and a lesser concentration of the inhibitor deeper at a second depth within the trench feature, the second depth being deeper within the trench feature than the first depth; and
operate the flow control hardware to perform a plurality of atomic layer deposition cycles, each atomic layer deposition cycle comprising controlling the flow control hardware to introduce the dielectric gapfill material precursor into the processing chamber, and then introduce the reactant into the processing chamber to fill the trench feature with dielectric gapfill material.

13. The atomic layer deposition tool of claim 12, wherein the inhibitor source comprises a halogen-containing inhibitor.

14. The atomic layer deposition tool of claim 12, wherein the inhibitor source comprises a nitrogen-containing inhibitor.

15. The atomic layer deposition tool of claim 12, wherein the inhibitor source comprises a carbon-containing inhibitor.

16. The atomic layer deposition tool of claim 12, wherein the controller is further configured to operate the atomic layer deposition tool to perform a passivation step to remove at least some of the inhibitor from the substrate.

17. A method of processing a substrate comprising a trench feature, the trench feature comprising a polysilicon surface, the polysilicon surface comprising reentrant features, the method comprising:
performing an inhibition cycle comprising depositing an inhibitor on the substrate under conditions that deposit a greater concentration of the inhibitor at a first depth within the trench feature than at a second depth within the trench feature, the second depth being deeper within the trench feature than the first depth;
performing a plurality of atomic layer deposition (ALD) cycles to fill the trench feature with a dielectric gapfill material, the inhibitor inhibiting growth of the dielectric gapfill material such that the dielectric gapfill material grows at a higher rate at the second depth relative to the first depth to fill the trench feature; and
processing a backside of the substrate to expose the dielectric gapfill material.

18. The method of claim 17, wherein the inhibitor comprises a halogen-containing inhibitor.

19. The method of claim 17, wherein the inhibitor comprises a nitrogen-containing inhibitor or a carbon-containing inhibitor.

20. The method of claim 17, wherein the trench feature is filled without a void.
